(19) United States
(12) Patent Application Publication
(10) Pub. No.: US 2021/0335518 A1
(43) Pub. Date: Oct. 28, 2021

(54) CONDUCTIVE FOAM TAPE AND DISPLAY PANEL

(71) Applicants: K-TRONICS (SUZHOU) TECHNOLOGY CO., LTD., Suzhou, Jiangsu (CN); BOE TECHNOLOGY GROUP CO., LTD., Beijing (CN)

(72) Inventor: Songlin LIU, Beijing (CN)

(21) Appl. No.: 16/318,542

(22) PCT Filed: Aug. 1, 2018
(86) PCT No.: PCT/CN2018/097902

§ 371 Date: Jan. 17, 2019

(30) Foreign Application Priority Data
Sep. 25, 2017 (CN) 201721239203.1

(51) Int. Cl. H01B 5/00; B32B 5/18; B32B 5/24; B32B 7/12

(52) U.S. Cl. CPC H01B 5/00; B32B 5/18; H05K 9/0067; B32B 7/12; B32B 5/245

(57) ABSTRACT

A conductive foam tape and a display panel are provided. The conductive foam tape includes a conductive foam and a conductive cloth layer disposed on an outside of the conductive foam. The conductive cloth layer has an extension portion protruding out of the conductive foam at least one end of the conductive foam tape.

The present application claims the priority of the Chinese Patent Application No. 201721239203.1 filed on Sep. 25, 2017, which is incorporated herein by reference as part of the disclosure of the present application.

### TECHNICAL FIELD

The embodiments of the present disclosure relate to a conductive foam tape and a display panel.

### BACKGROUND

Conductive foam tapes are widely used in a display panel. For example, the conductive foam tapes are used for electrically connecting electrical components in the display panel. For example, the conductive foam tapes are used for electrically connecting the display panel to external circuits. For example, the conductive foam tapes are used as antistatic components to conduct electrostatic charges accumulated on the display panel to outside of the display panel.

### SUMMARY

According to embodiments of the disclosure, a conductive foam tape is provided. The conductive foam tape comprises: a conductive foam and a conductive cloth layer disposed on an outside of the conductive foam. The conductive cloth layer has an extension portion protruding out of the conductive foam at at least one end of the conductive foam tape.

For example, the conductive cloth layer is wrapped around the conductive foam.

For example, a surface, facing away from the conductive foam, of at least a portion of the conductive cloth layer wrapped around the conductive foam has a first adhesive layer.

For example, the conductive foam is a cuboid and has a top surface, a bottom surface and two side surfaces, and the top surface, the bottom surface and the two side surfaces are all parallel to a length direction of the conductive foam tape; and a portion, disposed on at least one of the top surface, the bottom surface and the two side surfaces of the conductive foam, of the conductive cloth layer has the extension portion.

For example, at a same end of the conductive foam tape, a portion, disposed on at least one of the top surface, the bottom surface and the two side surfaces of the conductive foam, of the conductive cloth layer does not have the extension portion protruding out of the conductive foam.

For example, at a same end of the conductive foam tape, each of portions, respectively disposed on each of the top surface, the bottom surface and the two side surfaces of the conductive foam, of the conductive cloth layer has the extension portion protruding out of the conductive foam, but the extension portions have different lengths.

For example, a portion, disposed on the top surface of the conductive foam, of the conductive cloth layer has the extension portion.

For example, a portion, disposed on at least one of the two side surfaces of the conductive foam, of the conductive cloth layer has the extension portion.

For example, a surface, facing away from the conductive foam, of a portion, disposed on the bottom surface of the conductive foam, of the conductive cloth layer has a first adhesive layer.

For example, only one side of the conductive foam is provided with the conductive cloth layer.

For example, a thickness of the conductive cloth layer is less than or equal to a thickness of the conductive foam.

For example, a surface, facing away from the conductive cloth layer, of the conductive foam has a second adhesive layer.

For example, a thickness of the extension portion is from 0.1 mm to 0.2 mm.

For example, a length of the extension portion is from 5 mm to 10 mm.

For example, the extension portion is provided with a third adhesive layer.

For example, along a length direction of the conductive foam tape, the conductive cloth layer has the extension portion protruding out of the conductive foam respectively at two opposite ends of the conductive foam tape.

According to the embodiments of the disclosure, a display panel is provided. The display panel comprises: a frame and the conductive foam tape as described above. A plurality of conductive foam tapes are disposed on the frame, and the conductive foam tapes adjacent to each other are electrically connected with each other by the extension portions of the conductive foam tapes adjacent to each other.

For example, a space is between an edge of the frame and the conductive foam tape.

For example, orthographic projections of the conductive foams of the plurality of the conductive foam tapes on a plane where the frame is located do not overlap with each other.

### BRIEF DESCRIPTION OF THE DRAWINGS

In order to clearly illustrate the technical solution of the embodiments of the present disclosure, the drawings of the embodiments will be briefly described. It is apparent that the described drawings are only related to some embodiments of the present disclosure and thus are not limitative of the present disclosure.

FIG. 1 is a schematic diagram of a display panel according to one technique;

FIG. 2 is a sectional schematic diagram of a conductive foam tape provided by embodiments of the present disclosure;

FIG. 3 is a sectional schematic diagram of the conductive foam tape shown in FIG. 2 taken along another direction;

FIG. 4 is a stereoscopic diagram of a conductive foam of the conductive foam tape shown in FIG. 2;

FIG. 5 is another sectional schematic diagram of the conductive foam tape provided by the embodiments of the present disclosure;

FIG. 6 is a schematic diagram of a display panel provided by the embodiments of the present disclosure;

FIG. 7A is still another sectional schematic diagram of the conductive foam tape provided by the embodiments of the present disclosure;

FIG. 7B is a planar diagram of the conductive foam tape shown in FIG. 7A viewed from a side provided with a conductive cloth layer; and

FIG. 8 is still another sectional schematic diagram of the conductive foam tape provided by the embodiments of the present disclosure.

### DETAILED DESCRIPTION

In order to make objects, technical details and advantages of embodiments of the disclosure clear, the technical solutions of the embodiments will be described in a clearly and fully understandable way in connection with the related drawings. It is apparent that the described embodiments are just a part but not all of the embodiments of the disclosure. Based on the described embodiments herein, those skilled in the art can obtain, without any inventive work, other embodiment(s) which should be within the scope of the disclosure.

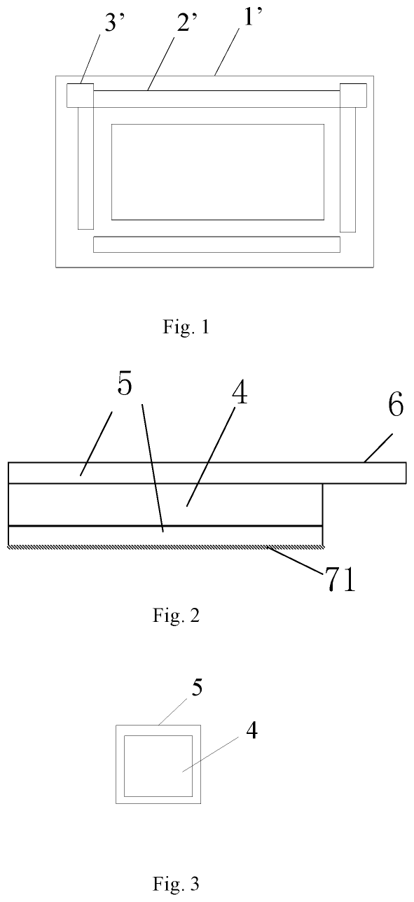

FIG. 1 is a schematic diagram of a display panel according to one technique. The display panel includes a front frame 1′ and conductive foam tapes 2′ disposed on a surface of the front frame 1′. For example, the front frame 1′ is a rectangle, and four sides of the front frame 1′ are respectively provided with the long strip-shaped conductive foam tapes 2′. Each of the conductive foam tapes 2′ has a certain thickness, and thus ends of the conductive foam tapes 2′ adjacent to each other cannot be directly overlapped with each other for electrical connecting, otherwise thicknesses at overlapping positions are increased significantly, which results in light leakage of the display panel. Because a conductive cloth is very thin, a thickness of a partial region, in which the conductive cloth is provided, of the display panel is not increased significantly, which thus does not lead to the light leakage of the display panel. Therefore, the conductive cloth 3′ is attached to ends of adjacent conductive foam tapes 2′ to electrically connect the adjacent conductive foam tapes 2′. However, the electrical connection method employing the conductive cloth increases process complexity of assembling the display panel, and wastes human resources.

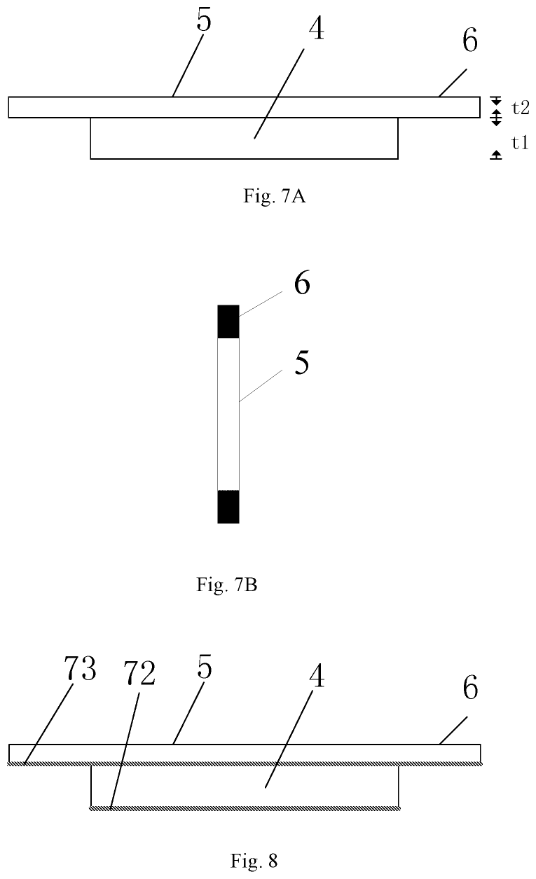

According to at least one embodiment of the present disclosure, a conductive foam tape is provided. FIG. 7A is a sectional schematic diagram of the conductive foam tape provided by at least one embodiment of the present disclosure, and FIG. 7B is a planar schematic diagram of the conductive foam tape shown in FIG. 7A viewed from a side provided with a conductive cloth layer. As illustrated in FIG. 7A and FIG. 7B, the conductive foam tape includes a conductive foam 4 and a conductive cloth layer 5 disposed on an outside of the conductive foam 4, and the conductive cloth layer 5 has an extension portion 6 protruding out of the conductive foam 4 at at least one end of the conductive foam tape. For example, the extension portion 6 acts as a connection portion of the conductive foam tape. In a process of assembling the display panel, the conductive foam tapes adjacent to each other are electrically connected with each other by the extension portions 6 thereof. For example, the extension portions 6 of the conductive foam tapes adjacent to each other are stacked to electrically connect the conductive foam tapes adjacent to each other. For example, for two conductive foam tapes adjacent to each other, the extension portion 6 of one of the two conductive foam tapes is attached or bonded to the conductive cloth layer 5 or the conductive foam 4 of the other of the two conductive foam tapes to electrically connect the conductive foam tapes adjacent to each other. In a case that the conductive foam tape according to at least one embodiment of the present disclosure is used to assemble the display panel, the light leakage does not occur, and it is also possible to electrically connect the conductive foam tapes adjacent to each other in a simple manner, which saves human resources and related costs, and a production efficiency is increased. For example, as illustrated in FIG. 7A and FIG. 7B, only one side of the conductive foam 4 is provided with the conductive cloth layer 5.

For example, at at least one end of the conductive foam tape along a length direction of the conductive foam tape, the conductive cloth layer 5 has the extension portion 6 protruding out of the conductive foam 4. For example, as illustrated in FIG. 7A and FIG. 7B, at two opposite ends of the conductive foam tape, the conductive cloth layer 5 has the extension portion 6 protruding out of the conductive foam 4.

For example, as illustrated in FIG. 7A and FIG. 7B, a thickness t2 of the conductive cloth layer 5 is less than a thickness t1 of the conductive foam 4, which prevents light leakage after assembling the display panel.

For example, as illustrated in FIG. 7A and FIG. 7B, the thickness t2 of the conductive cloth layer 5 is equal to the thickness t1 of the conductive foam 4. In a case that the thickness t2 of the conductive cloth layer 5 is equal to the thickness t1 of the conductive foam 4 and the extension portions 6 of the conductive foam tapes adjacent to each other are stacked, a sum of the thicknesses of the extension portions 6 of the conductive foam tapes adjacent to each other at stacking positions is the same as a thickness of a portion of each of the conductive foam tapes other than the extension portions 6, and a good thickness uniformity is achieved.

For example, as illustrated in FIG. 8, a surface of the extension portion 6 towards the conductive foam 4 is provided with a third adhesive layer 73, so that the extension portion 6 is able to be firmly fixed to another conductive foam tape or other components.

For example, as illustrated in FIG. 8, an entire surface of the conductive cloth layer 5 towards the conductive foam 4 is provided with the third adhesive layer 73. On one hand, the conductive cloth layer 5 is firmly fixed to the conductive foam 4. On the other hand, the extension portion 6 of the conductive cloth layer 5 is firmly fixed to another conductive foam tape or other components. For example, the third adhesive layer 73 is conductive.

For example, as illustrated in FIG. 8, a surface of the conductive foam 4 facing away from the conductive cloth layer 5 is provided with a second adhesive layer 72, so that the conductive foam tape is firmly fixed on other components such as the display panel. For example, the second adhesive layer 72 is also conductive.

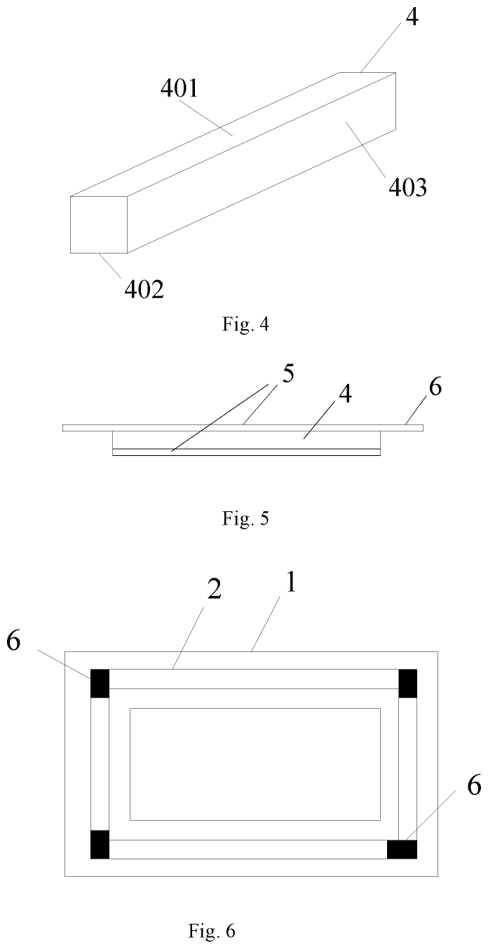

FIG. 2 is another sectional schematic diagram of the conductive foam tape provided by at least one embodiment of the present disclosure, FIG. 3 is a sectional schematic diagram of the conductive foam tape shown in FIG. 2 taken along another direction, and FIG. 4 is a stereoscopic diagram of the conductive foam of the conductive foam tape shown in FIG. 2. The sectional diagram illustrated in FIG. 2 is taken in a direction parallel to the length direction of the conductive foam tape, and the sectional diagram illustrated in FIG. 3 is taken in a direction perpendicular to the length direction of the conductive foam tape.

For example, as illustrated in FIG. 2, FIG. 3 and FIG. 4, the conductive foam tape includes the conductive foam 4 and the conductive cloth layer 5 disposed on the outside of the conductive foam 4. The conductive foam 4 has a flexibility and a light weight, and the conductive foam 4 acts as a base of conductive cloth layer 5. The conductive cloth layer 5 is conductive, and the conductive cloth layer 5 is fixed on an outer surface of the conductive foam 4.

For example, the conductive cloth layer 5 is wrapped around the conductive foam 4. In this case, for example, the conductive cloth layer 5 is wrapped on all surfaces of the conductive foam 4 parallel to the length direction of the conductive foam tape, and only a surface of the conductive foam 4 perpendicular to the length direction of the conductive foam tape is not provided with the conductive cloth layer 5.

For example, the conductive cloth layer 5 is wrapped around the conductive foam 4. In this case, in order to facilitate attaching the conductive foam tape to other components such as the display panel, as illustrated in FIG. 2, a surface, facing away from the conductive foam 4, of at least a portion of the conductive cloth layer 5 wrapped around the conductive foam 4 has a first adhesive layer 71. For example, the first adhesive layer 71 is conductive.

As illustrated in FIG. 2 to FIG. 4, for example, the conductive foam 4 is a cuboid, the conductive cloth layer 5 is wrapped around the conductive foam 4; that is, the conductive cloth layer 5 is fixed on a top surface 401, a bottom surface 402 and two side surfaces 403 of the conductive foam 4, and all of the top surface 401, the bottom surface 402 and the two side surfaces 403 of the conductive foam 4 are parallel to the length direction of the conductive foam tape. For example, a surface 402, facing away from the conductive foam 4, of a portion, disposed on the bottom surface 402 of the conductive foam 4, of the conductive cloth layer 5 has the first adhesive layer 71, and the first adhesive layer 71 is used for attaching the conductive foam tape onto other components such as the display panel. For example, a portion, disposed on at least one of the top surface 401, the bottom surface 402 and the two side surfaces 403 of the conductive foam 4, of the conductive cloth layer 5 has the extension portion 6. Furthermore, for example, at a same end of the conductive foam tape, a portion, disposed on at least one of the top surface 401, the bottom surface 402 and the two side surfaces 403 of the conductive foam 4, of the conductive cloth layer 5 does not have the extension portion 6 protruding out of the conductive foam, so as to prevent the portion, on each surface of the conductive foam 4, of the conductive cloth layer 5 has the extension portions 6 at the same end of the conductive foam tape, which avoids the increasing of the difficulty of connecting the conductive foam tape to other components. For example, in order to reduce the difficulty of connecting the conductive foam tape to other components, at the same end of the conductive foam tape, each of portions, respectively disposed on each of the top surface 401, the bottom surface 402 and the two side surfaces 403 of the conductive foam 4, of the conductive cloth layer 5 has the extension portion 6 protruding out of the conductive foam 4, but the extension portions 6 have different lengths. It should be noted that “the extension portions 6 have different lengths” means that at the same end of the conductive foam tape, the length of the extension portion 6 of the portion, disposed on at least one of the top surface 401, the bottom surface 402 and the two side surfaces 403 of the conductive foam 4, of the conductive cloth layer 5 is different from the lengths of the extension portions 6 of other portions of the conductive cloth layer 5.

For example, as illustrated in FIG. 2, at only one end of the conductive foam tape, the conductive cloth layer 5 has the extension portions 6 protruding out of the conductive foam 4. For example, as illustrated in FIG. 5, along the length direction of the conductive foam tape, the conductive cloth layer 5 has the extension portion 6 protruding out of the conductive foam 4 at two opposite ends of the conductive foam tape. The extension portion 6 act as the connection portion of the conductive foam tape. In a case of assembling the display panel, the conductive foam tapes adjacent to each other are electrically connected with each other by the extension portions 6 thereof. In a case that the conductive foam tape according to at least one embodiment of the present disclosure is used to assemble the display panel, the light leakage does not occur, and it is also possible to electrically connect the conductive foam tapes adjacent to each other in a simple manner, which saves human resources and related costs, and the production efficiency is increased.

The portion, disposed on at least one surface of the conductive foam 4, of the conductive cloth layers 5 is provided with the extension portion 6. The surface of conductive foam 4 includes the top surface 401, the bottom surface 402 and the two side surfaces 403, and the top surface 401, the bottom surface 402 and the two side surfaces 403 are all parallel to the length direction of the conductive foam tape. For example, as illustrated in FIG. 2, the portion, disposed on the top surface 401 of the conductive foam 4, of the conductive cloth layer 5 has the extension portion 6. In a case of assembling the display panel, the extension portion 6 on the top surface of the conductive foam 4 is directly attached or bonded to the conductive cloth layer 5 on the top surface of the other conductive foam tape adjacent thereto, to achieve that two conductive foam tapes 2 are connected with each other. For example, the portion, disposed on at least one of the two side surfaces 403 of the conductive foam 4, of the conductive cloth layers 5 has the extension portion 6. In a case of assembling the display panel, the extension portion 6 on at least one of the two side surfaces 403 of the conductive foam 4 is attached to the conductive cloth layer 5 on at least one of the two side surfaces 403 of the other conductive foam tape adjacent thereto, to achieve that two conductive foam tapes 2 are connected with each other. For example, the portion, disposed on the bottom surface 401 of the conductive foam 4, of the conductive cloth layer 5 has the extension portion 6. In a case of assembling the display panel, the extension portion 6 on the bottom surface of the conductive foam 4 is disposed below the conductive cloth layer 5 on the bottom surface of the other conductive foam tape adjacent thereto, to achieve that two conductive foam tapes 2 are connected with each other. According to the embodiments of the present disclosure, the connection modes of the adjacent conductive foam tapes is simple, and the assembly efficiency of the display panel is increased.

For example, a thickness of the extension portion 6 is from 0.1 mm to 0.2 mm, which prevents the light leakage after assembling the display panel. For example, a length of the extension portion 6 is from 5 mm to 10 mm. For example, as illustrated in FIG. 8, the extension portion 6 has the third adhesive layer 73 for bonding to other conductive components, which makes the extension portion 6 more tightly connected with other conductive components.

As illustrated in FIG. 2 to FIG. 4, the conductive cloth layer 5 is wrapped around the conductive foam 4; in a case of assembling the display panel, the extension portion 6 of the conductive foam tape is directly attached or bonded to any positions of an outer surface of the other conductive foam tape adjacent thereto, to achieve that two conductive foam tapes adjacent to each other are connected with each other. Therefore, the operation is simple and the efficiency of assembling the display panel is increased.

As illustrated in FIG. 6, at least one embodiment of the present disclosure further provides a display panel, and the display panel includes a frame 1 and a conductive foam tape 2 attached on the frame 1, and the conductive foam tape 2 is any one of the conductive foam tapes mentioned above. For example, the display panel includes a plurality of conductive foam tapes 2, and the plurality of conductive foam tapes 2 are respectively electrically connected with the conductive foam tapes 2 adjacent thereto by the extension portions 6. For example, the frame 1 is a front frame. For example, the frame 1 is a rectangular frame; the display panel includes four conductive foam tapes 2, and the four conductive foam tapes 2 are respectively provided on upper surfaces of four sides of the frame 1. The four conductive foam tapes 2 are respectively electrically connected with the adjacent conductive foam tapes 2 adjacent thereto by the extension portions 6, so that the four conductive foam tapes respectively provided on the four sides are joined together in an end-to-end manner to form an integral structure. Therefore, the operation is simple and the assembly efficiency of the display panel is increased.

In at least one embodiment of the present disclosure, orthographic projections of the conductive foams 4 of the plurality of the conductive foam tapes 2 on a plane where the frame 1 is located do not overlap with each other, that is, the conductive foams 4 of adjacent conductive foam tapes 2 do not overlap with each other. For example, a space is between the conductive foam tape 2 and an edge of the frame 1, so that the conductive foam tape 2 is not in contact with the edge of the frame 1, which prevents the conductive cloth layer 5 of the conductive foam tape 2 from being affected by the edge of the frame 1 to affect electrical conductivity of the conductive cloth layer 5.

What are described above is related to only the illustrative embodiments of the present disclosure and not limitative to the scope of protection of the present disclosure. The scope of protection of the present disclosure shall be defined by the accompanying claims.

1. A conductive foam tape, comprising: a conductive foam and a conductive cloth layer disposed on an outside of the conductive foam,
wherein the conductive cloth layer has an extension portion protruding out of the conductive foam at at least one end of the conductive foam tape.

2. The conductive foam tape according to claim 1, wherein the conductive cloth layer is wrapped around the conductive foam.

3. The conductive foam tape according to claim 2, wherein a surface, facing away from the conductive foam, of at least a portion of the conductive cloth layer wrapped around the conductive foam has a first adhesive layer.

4. The conductive foam tape according to claim 2, wherein
the conductive foam is a cuboid and has a top surface, a bottom surface and two side surfaces, and the top surface, the bottom surface and the two side surfaces are all parallel to a length direction of the conductive foam tape; and
a portion, disposed on at least one of the top surface, the bottom surface and the two side surfaces of the conductive foam, of the conductive cloth layer has the extension portion.

5. The conductive foam tape according to claim 4, wherein at a same end of the conductive foam tape, a portion, disposed on at least one of the top surface, the bottom surface and the two side surfaces of the conductive foam, of the conductive cloth layer does not have the extension portion protruding out of the conductive foam.

6. The conductive foam tape according to claim 4, wherein at a same end of the conductive foam tape, each of portions, respectively disposed on each of the top surface, the bottom surface and the two side surfaces of the conductive foam, of the conductive cloth layer has the extension portion protruding out of the conductive foam, but the extension portions have different lengths.

7. The conductive foam tape according to claim 4, wherein a portion, disposed on the top surface of the conductive foam, of the conductive cloth layer has the extension portion.

8. The conductive foam tape according to claim 4, wherein a portion, disposed on at least one of the two side surfaces of the conductive foam, of the conductive cloth layer has the extension portion.

9. The conductive foam tape according to claim 4, wherein a surface, facing away from the conductive foam, of a portion, disposed on the bottom surface of the conductive foam, of the conductive cloth layer has a first adhesive layer.

10. The conductive foam tape according to claim 1, wherein only one side of the conductive foam is provided with the conductive cloth layer.

11. The conductive foam tape according to claim 10, wherein a thickness of the conductive cloth layer is less than or equal to a thickness of the conductive foam.

12. The conductive foam tape according to claim 10, wherein a surface, facing away from the conductive cloth layer, of the conductive foam has a second adhesive layer.

13. The conductive foam tape according to claim 1, wherein a thickness of the extension portion is from 0.1 mm to 0.2 mm.

14. The conductive foam tape according to claim 1, wherein a length of the extension portion is from 5 mm to 10 mm.

15. The conductive foam tape according to claim 1, wherein the extension portion is provided with a third adhesive layer.

16. The conductive foam tape according to claim 1, wherein along a length direction of the conductive foam tape, the conductive cloth layer has the extension portion protruding out of the conductive foam respectively at two opposite ends of the conductive foam tape.

17. A display panel, comprising: a frame and the conductive foam tape according to claim 1, wherein a plurality of conductive foam tapes are disposed on the frame, and the conductive foam tapes adjacent to each other are electrically connected with each other by the extension portions of the conductive foam tapes adjacent to each other.

18. The display panel according to claim 17, wherein a space is between an edge of the frame and the conductive foam tape.

19. The display panel according to claim 17, wherein orthographic projections of the conductive foams of the plurality of the conductive foam tapes on a plane where the frame is located do not overlap with each other.
